(19) United States
(12) Patent Application Publication
(10) Pub. No.: US 2009/0214800 A1
(43) Pub. Date: Aug. 27, 2009

(54) APPARATUS FOR AND METHOD OF FORMING CARBON NANOTUBE

(76) Inventor: Kimitsugu Saito, Kyoto (JP)

Correspondence Address: OSTROLENK FABER GERB & SOFFEN, 1180 AVENUE OF THE AMERICAS, NEW YORK, NY, 100368403, US

(21) Appl. No.: 12/355,831

(22) Filed: Jan. 19, 2009

(30) Foreign Application Priority Data
Feb. 8, 2008 (JP) JP2008-028763

(51) Int. Cl. C23C 16/48

(52) U.S. Cl. 427/577; 118/723 R

(57) ABSTRACT

A vacuum chamber includes a radical beam irradiation part and a nanoparticle beam irradiation part. A substrate is held by a substrate holding part. The nanoparticle beam irradiation part irradiates the substrate with a beam of metal nanoparticles serving as a catalyst to form the catalyst on the substrate. Thereafter, the radical beam irradiation part generates a plasma from a source gas to irradiate the substrate with a beam of generated neutral radical species to grow a carbon nanotube on the substrate. The provision of an aperture in the radical beam irradiation part allows a relatively high degree of vacuum of 10⁻⁵ Torr to 10⁻³ Torr to be maintained in the vacuum chamber if the generation of the plasma involves a high pressure.

### BACKGROUND OF THE INVENTION

1. Field of the Invention

The present invention relates to an apparatus for and a method of forming a carbon nanotube which grow the carbon nanotube as a wiring material on a substrate such as a semiconductor wafer.

2. Description of the Background Art

In recent years, there has been a rapidly growing interest in an attempt to use a carbon nanotube as a BEOL (back-end-of-line) wiring material for LSI. Copper (Cu) has been generally used as a conventional wiring material. However, as patterns become finer for higher performance, current densities in wiring parts grow higher. It is expected that current densities too high for copper to withstand will be required in the near future. The carbon nanotube has a configuration such that a sheet of graphite (a graphene sheet) is rolled into a cylindrical shape, and has a diameter of several nanometers to tens of nanometers. It has been found that the carbon nanotube has very good electrical and mechanical characteristics. The carbon nanotube is a material having the potential to withstand a current density approximately a thousand times higher than that copper can withstand. For these reasons, there is a growing interest in the carbon nanotube as the wiring material.

The process of forming the carbon nanotube on a substrate is as follows. First, nanoparticles of cobalt (Co), nickel (Ni), iron (Fe) and the like serving as a catalyst are formed on the substrate serving as a base. Next, the carbon nanotube is grown on the metal nanoparticle catalyst. Chemical vapor deposition (CVD) techniques which are relatively suitable for mass production have been mainly under consideration as a technique for growing the carbon nanotube for LSI applications. Attempts have been made to use various CVD techniques such as thermal CVD, hot filament CVD, plasma CVD and the like. In particular, the plasma CVD technique receives attention. This is because a lower temperature is preferable in the process of forming the carbon nanotube as the BEOL wiring material, and the plasma CVD is the most promising technique for the decrease in the temperature in the above-mentioned process.

In the plasma CVD technique, a plasma is generated from a source gas containing hydrocarbons and the like. Various neutral radical species and ionic species are generated in the plasma. Using the neutral radical species positively as active species for the growth of the carbon nanotube while minimizing the contact of the ionic species with the substrate is found to be useful for the formation of the carbon nanotube of good quality. For example, US 2006/0078680 discloses a technique of generating a plasma (remote plasma) in a region separated from a substrate to prevent the substrate from being exposed to the plasma and also providing a mesh grid between the region in which the plasma is generated and the substrate to prevent ionic species from reaching the substrate.

However, the conventionally attempted plasma CVD techniques are not capable of forming the carbon nanotube of sufficient quality as the BEOL wiring material. From the viewpoint of industrial use, the conventional plasma CVD techniques have been impractical because of their low growth rate and low throughput.

As mentioned above, the process for forming the carbon nanotube on the substrate includes the following two steps: forming the nanoparticle catalyst on the substrate; and then growing the carbon nanotube by plasma CVD. In the conventional techniques, a procedure to be described below is followed. First, the metal nanoparticle catalyst is formed on the substrate in an apparatus other than a plasma CVD apparatus. Then, the substrate is removed out of the other apparatus and exposed to the outside atmosphere. Thereafter, the substrate is transported into the plasma CVD apparatus, and the carbon nanotube is grown on the substrate.

The process executed in such two steps presents a significant problem in which, because the substrate with the metal nanoparticle catalyst formed thereon is exposed to the atmosphere and then transported into the plasma CVD apparatus, the nanoparticle catalyst having an active surface is exposed to the atmosphere to become no longer active (or be inactivated), thereby no longer functioning as the catalyst for the formation of the carbon nanotube. There arise an additional problem in which the throughput is decreased as the substrate is transported into and out of the apparatuses, and the footprint of the entire production facilities is increased.

### SUMMARY OF THE INVENTION

The present invention is intended for a carbon nanotube forming apparatus for growing a carbon nanotube on a substrate.

According to one aspect of the present invention, the carbon nanotube forming apparatus comprises: a vacuum chamber for receiving a substrate therein; an evacuation element for maintaining a predetermined degree of vacuum in the vacuum chamber; a holding element for holding the substrate in the vacuum chamber; and a radical beam irradiation element for generating a plasma from a source gas containing carbon to emit neutral radical species present in the plasma, thereby irradiating the substrate held by the holding element with the neutral radical species.

While the predetermined degree of vacuum is maintained in the vacuum chamber for receiving the substrate therein, the radical beam irradiation element generates the plasma from the source gas containing carbon to irradiate the substrate with the neutral radical species present in the plasma. Thus, the carbon nanotube forming apparatus is capable of forming a carbon nanotube of high quality with a high throughput.

Preferably, the radical beam irradiation element includes a plasma generating chamber for introducing the source gas therein to generate the plasma, and an aperture plate provided at a distal end of the plasma generating chamber and having an aperture formed therein, and the radical beam irradiation element emits the neutral radical species through the aperture.

The aperture is provided at the distal end of the plasma generating chamber, and the radical beam irradiation element emits the neutral radical species through the aperture. This enables the predetermined degree of vacuum to be maintained in the vacuum chamber with reliability while the radical beam irradiation element generates the plasma.

Preferably, the carbon nanotube forming apparatus further comprises a nanoparticle beam irradiation element for emitting nanoparticles containing at least one type of metal selected from the group consisting of cobalt, nickel and iron to irradiate the substrate held by the holding element with the nanoparticles.

This prevents the nanoparticles formed on the substrate from being exposed to the atmosphere to accomplish the formation of the carbon nanotube without making the nanoparticles inactive.

Preferably, the carbon nanotube forming apparatus further comprises an ion arrival inhibition element for inhibiting ionic species leaking from the radical beam irradiation element from arriving at the substrate held by the holding element.

This inhibits the ionic species from arriving at the substrate to accomplish the formation of the carbon nanotube of higher quality.

Preferably, the carbon nanotube forming apparatus further comprises: a moving element for moving the holding element along a plane parallel to a main surface of the substrate held by the holding element; and a rotating element for rotating the holding element about the central axis of the substrate held by the holding element.

This allows the irradiation of the entire surface of the substrate with the neutral radical species emitted from the radical beam irradiation element.

The present invention is also intended for a method of growing a carbon nanotube on a substrate received in a vacuum chamber to form the carbon nanotube.

According to another aspect of the present invention, the method comprises the steps of: a) maintaining a predetermined degree of vacuum in the vacuum chamber; b) introducing a source gas containing carbon into a radical beam irradiation element to generate a plasma in the radical beam irradiation element; and c) emitting neutral radical species present in the generated plasma from the radical beam irradiation element to irradiate a substrate held in the vacuum chamber with the neutral radical species.

While the predetermined degree of vacuum is maintained in the vacuum chamber for receiving the substrate therein, the radical beam irradiation element generates the plasma from the source gas containing carbon to irradiate the substrate with the neutral radical species present in the plasma. Thus, the method is capable of forming a carbon nanotube of high quality with a high throughput.

Preferably, the neutral radical species are emitted from the radical beam irradiation element through an aperture formed in the radical beam irradiation element.

This enables the predetermined degree of vacuum to be maintained in the vacuum chamber with reliability while the radical beam irradiation element generates the plasma.

Preferably, the method further comprises the step of d) irradiating the substrate held in the vacuum chamber with nanoparticles containing at least one type of metal selected from the group consisting of cobalt, nickel and iron, the step d) being performed prior to the step c).

This prevents the nanoparticles formed on the substrate from being exposed to the atmosphere to accomplish the formation of the carbon nanotube without making the nanoparticles inactive.

It is therefore an object of the present invention to form a carbon nanotube of high quality with a high throughput.

It is another object of the present invention to form a carbon nanotube without making nanoparticles formed on a substrate inactive.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing the overall construction of a carbon nanotube forming apparatus according to the present invention;

FIG. 2 is a view showing the construction of a radical beam irradiation part;

FIG. 3 is a view showing the construction of a nanoparticle beam irradiation part;

FIG. 4A is a view showing an example of the construction of an ion arrival inhibition part;

FIG. 4B is a view showing another example of the construction of the ion arrival inhibition part;

FIG. 5 is a flow diagram showing a procedure for the process of forming a carbon nanotube in the apparatus of FIG. 1; and

FIG. 6 is a view showing another example of the construction of the radical beam irradiation part.

### DESCRIPTION OF THE PREFERRED EMBODIMENTS

A preferred embodiment according to the present invention will now be described in detail with reference to the drawings.

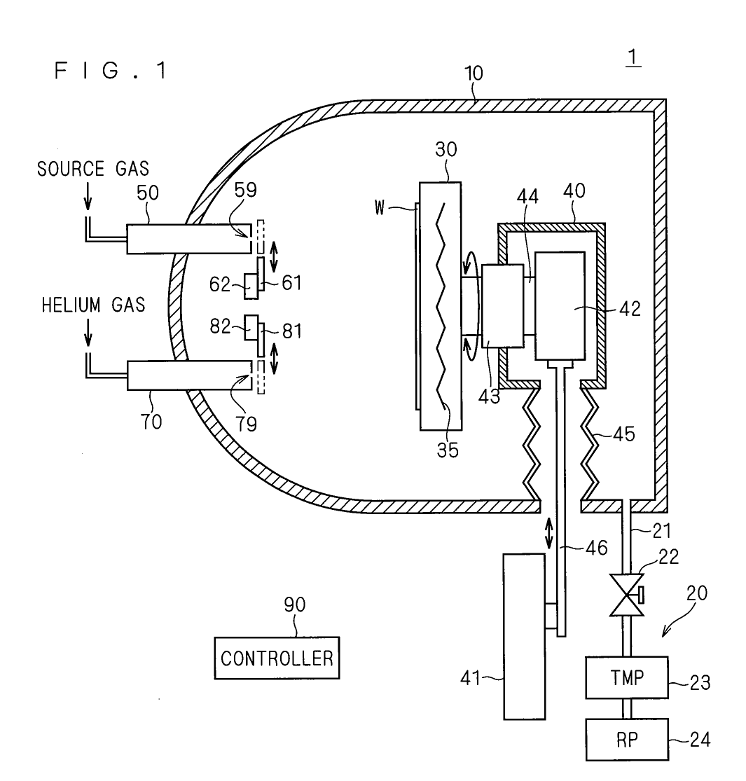

FIG. 1 is a view showing the overall construction of a carbon nanotube forming apparatus 1 according to the present invention. The carbon nanotube forming apparatus 1 according to the present invention is an apparatus for growing a carbon nanotube serving as a wiring material on a substrate such as a glass substrate for a liquid crystal display, for example, with a silicon film formed on the surface thereof, a semiconductor wafer, and the like. The carbon nanotube forming apparatus 1 is configured such that an evacuation mechanism 20, a substrate holding part 30, a radical beam irradiation part 50 and a nanoparticle beam irradiation part 70 are attached to a vacuum chamber 10. The carbon nanotube forming apparatus 1 further includes a controller 90 for controlling the operating mechanisms provided in the carbon nanotube forming apparatus 1 to execute the process of forming a carbon nanotube.

The vacuum chamber 10 is an enclosure made of metal (for example, made of stainless steel), and includes therein an enclosed space completely sealed against the outside space. The evacuation mechanism 20 includes a vacuum valve 22, a turbo molecular pump (TMP) 23, and a rotary pump (RP) 24. An exhaust pipe 21 is openly connected with the vacuum chamber 10. The exhaust pipe 21 is connected to the turbo molecular pump 23 and the rotary pump 24. The vacuum valve 22 is interposed in the exhaust pipe 21.

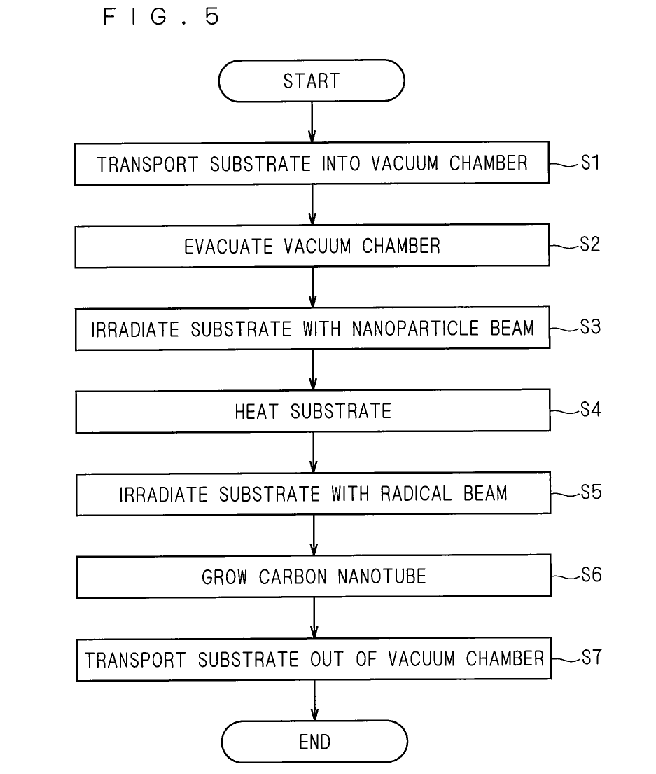

The rotary pump 24 is capable of operating even if the pressure in the vacuum chamber 10 is atmospheric pressure, and is used for initial roughing in an evacuation stroke (in Step S2 of FIG. 5). The turbo molecular pump 23 is a vacuum pump which rotates a turbine blade at high speeds to forcibly compress gas molecules, thereby discharging the gas molecules. The turbo molecular pump 23 is capable of maintaining the pressure in the vacuum chamber 10 at a relatively high degree of vacuum unattainable only by the rotary pump 24. In this preferred embodiment, the evacuation mechanism 20 including the turbo molecular pump 23 maintains the pressure in the vacuum chamber 10 during the processing at 10⁻⁵ Torr to 10⁻³ Torr. However, the turbo molecular pump 23 is capable of neither operating at a low vacuum close to atmospheric pressure nor compressing the gas molecules to atmospheric pressure. For these reasons, the rotary pump 24 is provided at the rear of the turbo molecular pump 23.

The substrate holding part 30 is a holder for holding a semiconductor wafer (referred to hereinafter as a substrate W) to be processed in the vacuum chamber 10. The substrate holding part 30 includes a plurality of gripping lugs (not shown) for gripping an end edge portion of the substrate W to thereby hold the substrate W. A portion of the substrate holding part 30 for contacting the back surface of the substrate W to be held is preferably made of ceramic which is less contaminated. A heater 35 for heating the substrate W held by the substrate holding part 30 is incorporated in the substrate holding part 30.

The substrate holding part 30 is rotatably supported by a drive box 40. Specifically, a motor 42 is fixed in the drive box 40 provided in the interior space of the vacuum chamber 10. The motor 42 has a motor shaft 44 which rotatably supports the substrate holding part 30. The motor shaft 44 is received in the drive box 40 through a bearing 43. The bearing 43 seals the inside space of the drive box 40 from the outside space thereof (i.e., the interior space of the vacuum chamber 10). The motor 42 has a rotational axis which is a central axis perpendicular to a main surface of the substrate W held by the substrate holding part 30, and rotates the substrate holding part 30 and the substrate W about the rotational axis.

The entire drive box 40 including the motor 42 is moved upwardly and downwardly (vertically as viewed in FIG. 1) by a lifting drive 41 to change its position. The lifting drive 41 is provided outside the vacuum chamber 10. The lifting drive 41 has a shaft 46 extending through an opening formed in a wall surface of the vacuum chamber 10 and an opening formed in the drive box 40 and coupled to the motor 42. The lifting drive 41 drives the shaft 46, to thereby cause the entire drive box 40 including the motor 42 to move upwardly and downwardly within the vacuum chamber 10. As the lifting drive 41 causes the drive box 40 to move upwardly and downwardly, the substrate holding part 30 and the substrate W held by the substrate holding part 30 move upwardly and downwardly along a plane parallel to the main surface of the substrate W within the vacuum chamber 10 to change their positions. An example of the lifting drive 41 used herein may include various known direct-acting mechanisms such as a screw feed mechanism using a ball screw and a belt feed mechanism using a belt and pulleys.

A bellows 45 capable of expansion and contraction provides communication between the opening in the drive box 40 and the opening in the vacuum chamber 10. The shaft 46 of the lifting drive 41 passes through the inside of the bellows 45. The bellows 45 expands when the drive box 40 is moved upwardly by the lifting drive 41, and contracts when the drive box 40 is moved downwardly by the lifting drive 41. The bellows 45 and the bearing 43 provide complete isolation between the atmosphere in the inside space of the drive box 40 and the atmosphere in the interior space of the vacuum chamber 10. The inside space of the drive box 40 and the outside of the vacuum chamber 10 are in communication with each other. Thus, if dust particles are generated from the motor 42 serving as a drive and the lifting drive 41, the dust particles are prevented from entering the interior space of the vacuum chamber 10. A mechanism for rotating and moving the substrate holding part 30 and the substrate W is not limited to the above-mentioned configuration shown in FIG. 1, but is required only to be configured to rotate the substrate W about the central axis and to move the substrate W in parallel to the main surface thereof. For example, the lifting drive 41 may be provided within the vacuum chamber 10. However, complete isolation is preferably provided between the atmosphere around the motor 42 and the lifting drive 41 and the atmosphere in the interior space of the vacuum chamber 10. A mechanism for horizontally moving the substrate holding part 30 in two axial directions may be used in place of the motor 42 and the lifting drive 41.

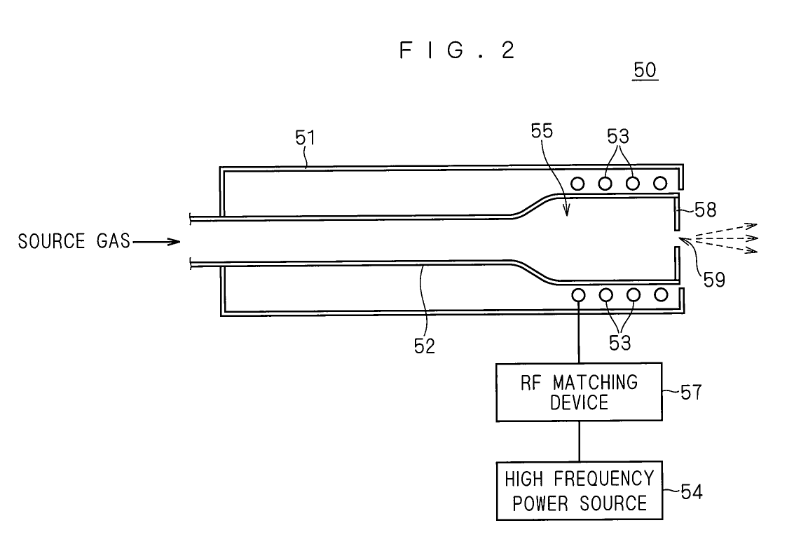

The radical beam irradiation part 50 is provided to penetrate through the wall surface of the vacuum chamber 10. FIG. 2 is a view showing the construction of the radical beam irradiation part 50. The radical beam irradiation part 50 has an RF-ICP device for generating an inductively coupled plasma. The radical beam irradiation part 50 includes a casing 51, an insulative discharge tube 52 provided in the casing 51, and an induction coil 53 provided in the casing 51. A source gas is supplied from a source gas supply source not shown to the discharge tube 52 at its proximal end. The source gas used herein includes hydrocarbon gas such as acetylene (C₂H₂), ethylene (C₂H₄), methane (CH₄) and the like, or vaporized alcohol. In other words, the source gas is a gas containing carbon (C). Hydrogen (H₂), argon (Ar) or vaporized water serving as a diluent may be added to the source gas.

The induction coil 53 is disposed around a distal end portion of the discharge tube 52. A high frequency power source 54 is connected to the induction coil 53 through an RF matching device 57 serving as a device for decreasing the ratio of the reflection to the input of a high frequency. The inside space of the discharge tube 52 surrounded by the induction coil 53 serves as a plasma generating chamber 55. Specifically, a plasma is generated in the plasma generating chamber 55 when the high frequency power source 54 passes a large high-frequency current through the induction coil 53 while the source gas is fed from the proximal end of the discharge tube 52.

An aperture plate 58 is provided so as to cover an opening at the distal end of the discharge tube 52. The aperture plate 58 has an aperture 59 provided in a central portion of the aperture plate 58 and extending through the aperture plate 58. The aperture 59 is a small circular hole having a diameter of 1 mm to 10 mm. When a plasma is generated in the plasma generating chamber 55, neutral radical species are emitted from the aperture 59.

The radical beam irradiation part 50 is placed so that the aperture 59 is opposed to the substrate W held by the substrate holding part 30. Specifically, the direction through which the aperture 59 is bored is perpendicular to the main surface of the substrate W held by the substrate holding part 30, and the substrate W is positioned on the extension of the above-mentioned direction. Thus, the substrate W held by the substrate holding part 30 is irradiated with a beam of neutral radical species emitted from the aperture 59 and traveling in a straight line. The radical beam irradiation part 50 may be placed so that the direction through which the aperture 59 is bored is substantially perpendicular to the main surface of the substrate W, and may obliquely irradiate the substrate W with the beam of neutral radical species.

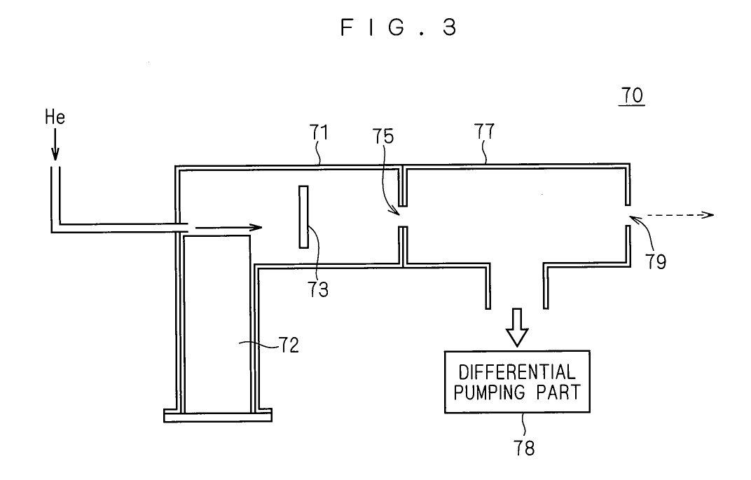

The nanoparticle beam irradiation part 70 is also provided to penetrate through the wall surface of the vacuum chamber 10. FIG. 3 is a view showing the construction of the nanoparticle beam irradiation part 70. The nanoparticle beam irradiation part 70 generates and emits nanoparticles of metal functioning as a catalyst for the formation of the carbon nanotube (metal containing cobalt (Co), nickel (Ni), iron (Fe) and the like as a main component, and containing molybdenum (Mo), titanium (Ti), titanium nitride (TiN), chromium (Cr), aluminum (Al) and alumina (Al₂O₃) as an additive in trace amounts). The nanoparticle beam irradiation part 70 includes a nanoparticle generating chamber 71, and an intermediate chamber 77 connected to the nanoparticle generating chamber 71. The nanoparticle beam irradiation part 70 may generate nanoparticles from at least one type of metal selected from the group consisting of cobalt, nickel and iron without using any additive.

The nanoparticle generating chamber 71 includes a K cell (Knudsen cell) 72, and an impactor 73. Metal (cobalt in this preferred embodiment) serving as a raw material is placed in the K cell 72. By heating the K cell 72, cobalt vapor is released upwardly of the K cell 72. For example, helium (He) gas is supplied from a gas supply source not shown to the nanoparticle generating chamber 71 toward a space over the K cell 72. The supplied helium gas forms a flow directed from left to right as viewed in FIG. 3 within the nanoparticle generating chamber 71. This helium gas flow causes cobalt atoms vaporized from the K cell 72 to collide with each other and cluster together repeatedly, thereby forming cobalt nanoparticles in a vapor phase.

The formed cobalt nanoparticles are carried by the helium gas flow. The impactor 73 classifies the cobalt nanoparticles by size to remove nanoparticles having a size equal to or greater than a predetermined size. The nanoparticles having a size less than the predetermined size and passing through the impactor 73 are introduced through a first aperture 75 which is an opening at a connection between the nanoparticle generating chamber 71 and the intermediate chamber 77 into the intermediate chamber 77.

The intermediate chamber 77 is a differential pumping chamber such that a differential pumping part 78 which is an exhausting part separate from the evacuation mechanism 20 exhausts the gas from a space surrounded by the first aperture 75 and a second aperture 79 to decrease the pressure in the intermediate chamber 77 stepwise. The cobalt nanoparticles introduced into the intermediate chamber 77 are emitted through the second aperture 79 into the vacuum chamber 10. The helium gas and cobalt vapor supplied to the nanoparticle generating chamber 71 cause the pressure in the nanoparticle generating chamber 71 to reach tens of millitorrs to hundreds of millitorrs. Thus, the degree of vacuum in the nanoparticle generating chamber 71 is significantly low, as compared with that in the vacuum chamber 10. However, the degree of vacuum in the vacuum chamber 10 is maintained by the provision of the intermediate chamber 77 functioning as the differential pumping chamber.

The nanoparticle beam irradiation part 70 is placed so that the second aperture 79 is opposed to the substrate W held by the substrate holding part 30. Specifically, the direction through which the second aperture 79 is bored is perpendicular to the main surface of the substrate W held by the substrate holding part 30, and the substrate W is positioned on the extension of the above-mentioned direction. Thus, the substrate W held by the substrate holding part 30 is irradiated with a beam of nanoparticles emitted from the second aperture 79 and traveling in a straight line. The nanoparticle beam irradiation part 70 may be placed so that the direction through which the second aperture 79 is bored is substantially perpendicular to the main surface of the substrate W, and may obliquely irradiate the substrate W with the beam of nanoparticles.

As shown in FIG. 1, a shutter 61 is capable of shielding the front of the radical beam irradiation part 50. A shutter drive 62 moves the shutter 61 to a position indicated by dash-double-dot lines in FIG. 1 to shut off the beam of neutral radical species directed from the radical beam irradiation part 50 toward the substrate W held by the substrate holding part 30. When the shutter 61 is moved to a position indicated by solid lines in FIG. 1 by the shutter drive 62, the beam of neutral radical species from the radical beam irradiation part 50 is allowed to impinge upon the substrate W.

Similarly, a shutter 81 is capable of shielding the front of the nanoparticle beam irradiation part 70. A shutter drive 82 moves the shutter 81 to a position indicated by dash-double-dot lines in FIG. 1 to shut off the beam of nanoparticles directed from the nanoparticle beam irradiation part 70 toward the substrate W held by the substrate holding part 30. When the shutter 81 is moved to a position indicated by solid lines in FIG. 1 by the shutter drive 82, the beam of nanoparticles from the nanoparticle beam irradiation part 70 is allowed to impinge upon the substrate W.

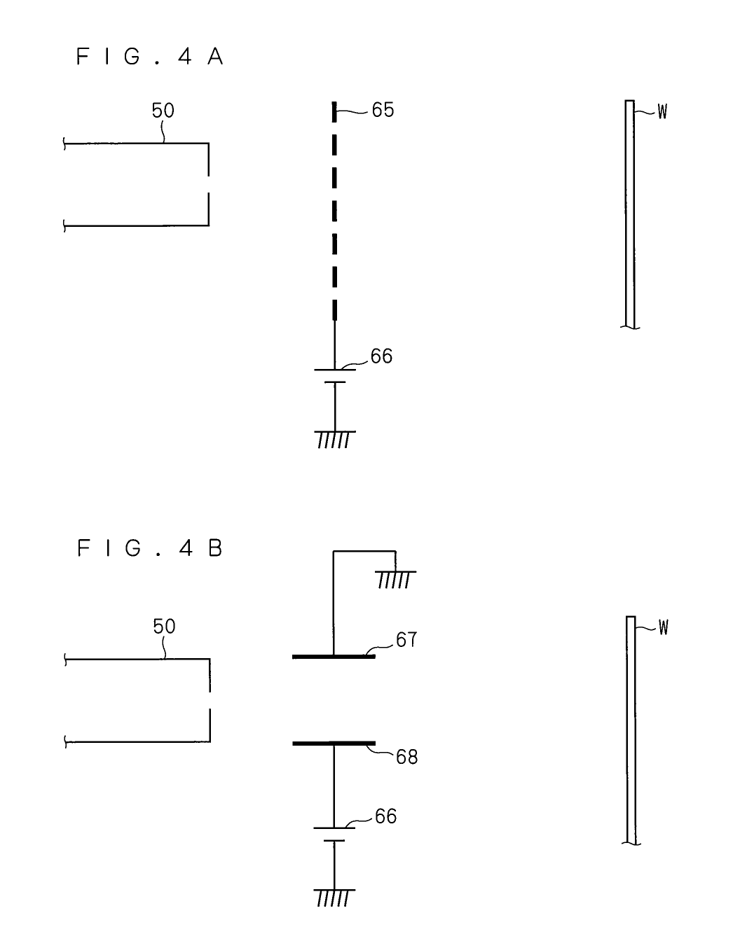

The carbon nanotube forming apparatus 1 further includes parts provided between the radical beam irradiation part 50 and the substrate holding part 30 and for preventing ionic species from arriving at the substrate W, as illustrated in FIGS. 4A and 4B (although not shown in FIG. 1). In an instance shown in FIG. 4A, a mesh grid 65 made of metal is disposed between the radical beam irradiation part 50 and the substrate W held by the substrate holding part 30. A bias supply 66 applies a predetermined bias voltage to the mesh grid 65. This makes it impossible for the ionic species released from the radical beam irradiation part 50 to pass through the mesh grid 65, thereby preventing the ionic species from arriving at the substrate W.

In an instance shown in FIG. 4B, a pair of metal plates 67 and 68 are disposed on opposite sides of a path directed from the radical beam irradiation part 50 toward the substrate W held by the substrate holding part 30. The metal plate 67 is grounded. The bias supply 66 applies a predetermined bias voltage to the metal plate 68. This produces an electric field between the pair of metal plates 67 and 68. The electric field significantly deflects the course of the ionic species released from the radical beam irradiation part 50 to prevent the ionic species from arriving at the substrate W.

The controller 90 controls the various operating mechanisms provided in the carbon nanotube forming apparatus 1. The controller 90 is similar in hardware construction to a typical computer. Specifically, the controller 90 includes a CPU for performing various computation processes, a ROM or read-only memory for storing a basic program therein, a RAM or readable/writable memory for storing various pieces of information therein, and a magnetic disk for storing control software and data therein.

The carbon nanotube forming apparatus 1 further includes various known mechanisms as those for a vacuum device in addition to the above-mentioned components. For example, the vacuum chamber 10 includes a transport opening for transporting the substrate W therethrough into and out of the vacuum chamber 10, a vacuum indicator for measuring the degree of vacuum in the interior space, a cooling mechanism for preventing temperature from increasing due to heat generated from the heater 35, a leak valve for opening the interior space to the atmosphere, and the like (all not shown).

Next, description will be given on the process of forming a carbon nanotube in the carbon nanotube forming apparatus 1 having the above-mentioned construction. FIG. 5 is a flow diagram showing a procedure for the process of forming a carbon nanotube in the carbon nanotube forming apparatus 1. The procedure for the process of forming a carbon nanotube to be described below is executed by the controller 90 controlling the various operating mechanisms of the carbon nanotube forming apparatus 1.

First, a substrate W to be processed is transported into the vacuum chamber 10, and is held by the substrate holding part 30 (in Step S1). To maintain the degree of vacuum in the vacuum chamber 10, a load lock chamber may be attached to the vacuum chamber 10 so that the substrate W is transported into and out of the vacuum chamber 10 by way of the load lock chamber.

Subsequently, the vacuum chamber 10 is evacuated (in Step S2). The evacuation of the vacuum chamber 10 is performed by the evacuation mechanism 20. For the evacuation of the vacuum chamber 10 from atmospheric pressure, the roughing is performed by the rotary pump 24 while opening the vacuum valve 22. Then, after a predetermined degree of vacuum is reached, the turbo molecular pump 23 is operated to cause the degree of vacuum in the vacuum chamber 10 to reach 10⁻⁷ Torr to 10⁻⁴ Torr as a pre-processing state. When the above-mentioned load lock chamber is used to transport the substrate W therethrough into and out of the vacuum chamber 10, a certain degree of vacuum is attained in the vacuum chamber 10. For this reason, both the rotary pump 24 and the turbo molecular pump 23 may be operated in the initial stage of Step S2 to cause the degree of vacuum in the vacuum chamber 10 to reach 10⁻⁷ Torr to 10⁻⁴ Torr.

After the degree of vacuum in the vacuum chamber 10 reaches 10⁻⁷ Torr to 10⁻⁴ Torr, a cobalt nanoparticle beam is emitted from the nanoparticle beam irradiation part 70 toward the substrate W (in Step S3). The nanoparticle beam irradiation part 70 generates cobalt particles in a manner as mentioned above. The nanoparticle beam irradiation part 70 emits the cobalt nanoparticle beam through the second aperture 79 of the intermediate chamber 77, and the nanoparticles arrive at the surface of the substrate W held by the substrate holding part 30. During the generation of the nanoparticles, the pressure in the nanoparticle generating chamber 71 of the nanoparticle beam irradiation part 70 is considerably higher than that in the vacuum chamber 10. However, the degree of vacuum in the vacuum chamber 10 is maintained at about 10⁻⁵ Torr to about 10⁻³ Torr because differential pumping is performed by the intermediate chamber 77.

Since a relatively high degree of vacuum of 10⁻⁵ Torr to 10⁻³ Torr is maintained in the vacuum chamber 10 during the processing, the cobalt nanoparticle beam emitted from the nanoparticle beam irradiation part 70 travels in a straight line substantially without attenuation to impinge upon the surface of the substrate W. It should be noted that the area irradiated with the nanoparticle beam is significantly small, as compared with the area of the substrate W. As an example, assuming that the substrate W is a semiconductor wafer having a diameter of 300 mm, the area irradiated with the nanoparticle beam has a diameter of several centimeters. Thus, the motor 42 rotates the substrate W and the lifting drive 41 moves the substrate W upwardly and downwardly to move the substrate W in parallel with and relative to the nanoparticle beam irradiation part 70 so that the entire surface of the substrate W is irradiated with the nanoparticle beam.

The irradiation of the surface of the substrate W with the cobalt nanoparticle beam causes a catalyst for growing a carbon nanotube to be formed on the surface of the substrate W. During the irradiation with the nanoparticle beam, the heater 35 is not in operation, and the catalyst is formed at room temperature.

After the formation of the catalyst by the irradiation of the entire surface of the substrate W with the cobalt nanoparticle beam, the emission of the nanoparticle beam from the nanoparticle beam irradiation part 70 is stopped, and the heater 35 is brought into operation to heat the substrate W (in Step S4). In this preferred embodiment, the substrate W is heated to a temperature of 350° C. to 400° C. corresponding to a process temperature required for the growth of the carbon nanotube. The substrate holding part 30 includes a temperature measuring part (e.g., a thermocouple) not shown which monitors the temperature of the substrate W.

After the temperature of the substrate W reaches a predetermined process temperature, a beam of neutral radical species is emitted from the radical beam irradiation part 50 toward the substrate W (in Step S5). Specifically, a large high-frequency current is passed through the induction coil 53 while the source gas is fed to the discharge tube 52 to generate an inductively coupled plasma in the plasma generating chamber 55 at the distal end of the discharge tube 52. Various neutral radical species and ionic species are generated in the plasma generated in the plasma generating chamber 55. Of these species, most of the ionic species which are charged particles are confined in the plasma, and the radical species which are electrically neutral are emitted through the aperture 59 provided at the distal end of the plasma generating chamber 55. In this manner, the radical beam irradiation part 50 emits the beam of neutral radical species through the aperture 59, and the neutral radical species arrive at the surface of the substrate W held by the substrate holding part 30.

For the generation of the plasma, the source gas is fed to the discharge tube 52 to cause an electrical discharge to occur in the plasma generating chamber 55. Thus, the gas pressure in the discharge tube 52 reaches several millitorrs to tens of millitorrs. In the radical beam irradiation part 50 according to this preferred embodiment, the aperture 59 which is formed at the distal end of the plasma generating chamber 55 serves as resistance against the movement of the gas from the discharge tube 52 to the vacuum chamber 10. For this reason, when the evacuation mechanism 20 has a sufficient exhaust capability similar to that of some type of differential pumping, the gas pressure in the discharge tube 52 reaches several millitorrs to tens of millitorrs whereas the degree of vacuum of 10⁻⁵ Torr to 10⁻³ Torr is maintained in the vacuum chamber 10.

Since the relatively high degree of vacuum is maintained in the vacuum chamber 10, the beam of neutral radical species emitted from the radical beam irradiation part 50 travels in a straight line substantially without attenuation to impinge upon the surface of the substrate W. Like the area irradiated with the nanoparticle beam described above, the area irradiated with the beam of neutral radical species is significantly small, as compared with the area of the substrate W. Thus, the motor 42 rotates the substrate W and the lifting drive 41 moves the substrate W upwardly and downwardly to move the substrate W in parallel with and relative to the radical beam irradiation part 50 so that the entire surface of the substrate W is irradiated with the beam of neutral radical species.

The irradiation of the substrate W heated to a temperature of 350° C. to 400° C. with the beam of neutral radical species causes a carbon nanotube to grow on the catalyst on the surface of the substrate W (in Step S6). In some cases, the ionic species in the plasma leak slightly from the aperture 59. However, the mechanism shown in FIG. 4A or FIG. 4B which is provided between the radical beam irradiation part 50 and the substrate holding part 30 inhibits such leaking ionic species from arriving at the surface of the substrate W.

After the carbon nanotube is grown by irradiating the entire surface of the substrate W with the beam of neutral radical species for a predetermined length of time, the emission of the beam of neutral radical species from the radical beam irradiation part 50 and the heating using the heater 35 are stopped. Then, the processed substrate W is transported out of the vacuum chamber 10. This completes the process of forming the carbon nanotube (in Step S7).

The carbon nanotube forming apparatus 1 according to this preferred embodiment includes the intermediate chamber 77 serving as the differential pumping chamber in the nanoparticle beam irradiation part 70, and the aperture 59 in the radical beam irradiation part 50. This forms a kind of differential pumping system in both the radical beam irradiation part 50 and the nanoparticle beam irradiation part 70. When the evacuation mechanism 20 has a sufficient exhaust capability, the relatively high degree of vacuum of 10⁻⁵ Torr to 10⁻³ Torr is maintained in the vacuum chamber 10.

As mentioned above, the process temperature is preferably lower for the formation of the carbon nanotube as a BEOL wiring material. In this preferred embodiment, the process temperature is a relatively low temperature ranging from 350° C. to 400° C. To increase the quality and growth rate of the carbon nanotube at such a relatively low process temperature, it is necessary to accordingly decrease a process pressure. It has been observed that a suitable process pressure is approximately 1 mTorr or less when the process temperature range from 350° C. to 400° C. The carbon nanotube forming apparatus 1 according to this preferred embodiment maintains the relatively high degree of vacuum of 10⁻⁵ Torr to 10⁻³ Torr in the vacuum chamber 10 to thereby increase the quality and growth rate of the carbon nanotube if the temperature (the process temperature) for heating the substrate W is a relatively low temperature ranging from 350° C. to 400° C. As a result, the carbon nanotube forming apparatus 1 is capable of forming a carbon nanotube of high quality with a high throughput.

On the other hand, it is generally difficult to generate a plasma under an atmosphere having a relatively high degree of vacuum of 10⁻⁵ Torr to 10⁻³ Torr. The carbon nanotube forming apparatus 1 according to this preferred embodiment performs a kind of differential pumping by the provision of the aperture 59 in the radical beam irradiation part 50 to attain the gas pressure of several millitorrs to tens of millitorrs in the discharge tube 52. Thus, the carbon nanotube forming apparatus 1 is capable of generating the inductively coupled plasma in the plasma generating chamber 55.

In the carbon nanotube forming apparatus 1 according to this preferred embodiment, the single vacuum chamber 10 is provided with both the radical beam irradiation part 50 and the nanoparticle beam irradiation part 70. This enables the two-step process of forming the nanoparticle catalyst on the substrate W and thereafter growing the carbon nanotube to be executed throughout in a vacuum without transporting the substrate W out of the vacuum chamber 10. Since the substrate W with the nanoparticle catalyst formed thereon is not exposed to the atmosphere, the carbon nanotube forming apparatus 1 does not make the nanoparticles inactive but causes the nanoparticles to effectively function as the catalyst, thereby accomplishing the formation of the carbon nanotube. This also prevents the decrease in throughput resulting from the transfer of the substrate W, and achieves the reduction in footprint of the entire carbon nanotube forming apparatus 1.

Additionally, since the relatively high degree of vacuum of 10⁻⁵ Torr to 10⁻³ Torr is maintained in the vacuum chamber 10, the formation of the nanoparticle catalyst and the growth of the carbon nanotube are executed under conditions of pressure generally close to that in a molecular flow region. This minimizes the mutual interference between the emission of the beam of neutral radical species from the radical beam irradiation part 50 and the emission of the nanoparticle beam from the nanoparticle beam irradiation part 70. If the degree of vacuum in the vacuum chamber 10 is low and the process is executed under conditions of pressure obtained in a viscous flow region, there is a danger that the neutral radical species emitted from the radical beam irradiation part 50 diffuse to enter the nanoparticle beam irradiation part 70 or that the nanoparticles emitted from the nanoparticle beam irradiation part 70 enter the radical beam irradiation part 50. This preferred embodiment substantially eliminates the danger of such mutual interference because the emission of the beam of neutral radical species and the emission of the nanoparticle beam are performed under conditions of pressure close to that in a molecular flow region.

The neutral radical species are mainly emitted from the aperture 59 of the radical beam irradiation part 50, but the ionic species slightly leak therefrom. Such ionic species might interfere with the formation of the carbon nanotube of high quality. The carbon nanotube forming apparatus 1 according to this preferred embodiment, however, includes the mechanism provided between the radical beam irradiation part 50 and the substrate holding part 30 as shown in FIG. 4A or FIG. 4B to prevent the ionic species from arriving at the surface of the substrate W, thereby forming the carbon nanotube of high quality.

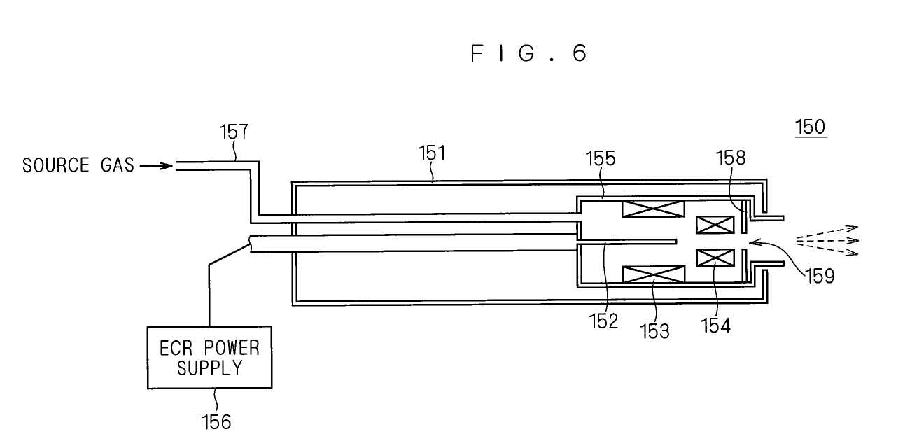

While the preferred embodiment according to the present invention has been described hereinabove, various modifications of the present invention in addition to those described above may be made without departing from the scope and spirit of the invention. For example, the radical beam irradiation part 50 of the RF-ICR type which passes the large high-frequency current through the induction coil 53 to generate the inductively coupled plasma from the source gas is used as a radical beam irradiation source in the above-mentioned preferred embodiment, but the radical beam irradiation source according to the present invention may be a radical beam irradiation part 150 as shown in FIG. 6. The radical beam irradiation part 150 shown in FIG. 6 includes an ECR device for generating an ECR (electron cyclotron resonance) plasma.

The radical beam irradiation part 150 includes a casing 151, and a plasma generating chamber 155 provided in the casing 151. An antenna 152, a permanent magnet 153 and an ion removal magnet 154 are provided within the plasma generating chamber 155. A source gas is supplied from a source gas supply source not shown through a gas feed pipe 157 into the interior space of the plasma generating chamber 155. This source gas is similar to that of the above-mentioned preferred embodiment, and is a gas containing at least carbon (C). An ECR power supply 156 is connected to the antenna 152.

A magnetic field is applied in the plasma generating chamber 155 by the permanent magnet 153. When a microwave (e.g. at 2.45 GHz) is fed from the ECR power supply 156 to the antenna 152 while the source gas is supplied in this state, the effect of electron cyclotron resonance generates a plasma in the plasma generating chamber 155. Such an ECR scheme is characterized by generating a very dense plasma under a lower pressure (approximately 10⁻⁴ Torr), as compared with the RF-ICP scheme of the above-mentioned preferred embodiment.

An aperture plate 158 is provided at the distal end of the plasma generating chamber 155. The aperture plate 158 has an aperture 159 provided in a central portion of the aperture plate 158. The ion removal magnet 154 is provided to remove the ionic species from the plasma generated in the plasma generating chamber 155.

Various neutral radical species and ionic species are also generated in the plasma generated in the plasma generating chamber 155 by the effect of electron cyclotron resonance. Of these species, the ionic species are removed by the ion removal magnet 154, and the radical species which are electrically neutral are emitted through the aperture 159 provided at the distal end of the plasma generating chamber 155. In this manner, the radical beam irradiation part 150 emits a beam of neutral radical species through the aperture 159, and the neutral radical species arrive at the surface of the substrate W held by the substrate holding part 30.

When the radical beam irradiation part 150 of the ECR type which uses the effect of electron cyclotron resonance to generate the plasma is used as the radical beam irradiation source, the area irradiated with the beam of neutral radical species is also significantly small, as compared with the area of the substrate W. Thus, the motor 42 rotates the substrate W and the lifting drive 41 moves the substrate W upwardly and downwardly so that the entire surface of the substrate W is irradiated with the beam of neutral radical species. When the radical beam irradiation part 150 of the ECR type is used, effects similar to those of the above-mentioned preferred embodiment are produced by executing a procedure similar to that of the above-mentioned preferred embodiment.

The aperture 159 need not necessarily be provided because the radical beam irradiation part 150 of the ECR type is capable of generating a plasma at the degree of vacuum approximately equal to that in the vacuum chamber 10. On the other hand, the ion removal magnet 154 is essential for the growth of the carbon nanotube of high quality by using the neutral radical species because a relatively large number of ionic species are generated in the ECR plasma. Preferably, the mechanism as shown in FIG. 4A or FIG. 4B is provided between the radical beam irradiation part 150 and the substrate holding part 30 to prevent the ionic species from arriving at the surface of the substrate W with reliability.

The nanoparticle beam irradiation part 70 according to the above-mentioned preferred embodiment produces the cobalt vapor by heating the K cell 72. Instead, the cobalt vapor may be produced by laser ablation using cobalt as a target. The production of the cobalt vapor is not limited to these techniques. For example, the cobalt vapor may be produced by DC (direct current) sputtering using a cobalt target. When the DC sputtering is used, a quadrupole mass filter may be used for the classification by size in place of the impactor 73.

Although the nanoparticle beam irradiation part 70 according to this preferred embodiment includes the intermediate chamber 77 for differential pumping, the intermediate chamber 77 need not be provided when the evacuation mechanism 20 has a sufficiently high exhaust capability. In this case, the cobalt nanoparticle beam is emitted from the first aperture 75 into the vacuum chamber 10.

The metal serving as the raw material of the catalyst for the growth of the carbon nanotube is not limited to cobalt, but may be nickel, iron or an alloy containing at least one selected from the group consisting of cobalt, nickel and iron.

In the above-mentioned preferred embodiment, the evacuation mechanism 20 is comprised of a combination of the turbo molecular pump 23 and the rotary pump 24. The construction of the evacuation mechanism 20, however, is not limited to this. For example, a combination of a diffusion pump (DP) and a rotary pump which can maintain the degree of vacuum of 10⁻⁵ Torr to 10⁻³ Torr in the vacuum chamber 10 may constitute the evacuation mechanism 20.

In the above-mentioned preferred embodiment, the shutters 61 and 81 are disposed in proximity to the radical beam irradiation part 50 and the nanoparticle beam irradiation part 70. In place of or in addition to the shutters 61 and 81, at least one shutter may be provided immediately in front of the substrate W held by the substrate holding part 30. Such at least one shutter immediately in front of the substrate W may include individual shutters for the radical beam and the nanoparticle beam respectively or be a single common shutter shared therebetween.

When the turbo molecular pump (TMP) 23 has a sufficiently high exhaust capability, the intermediate chamber 77, the differential pumping part 78 and the second aperture 79 in the nanoparticle beam irradiation part 70 shown in FIG. 3 may be dispensed with.

While the invention has been described in detail, the foregoing description is in all aspects illustrative and not restrictive. It is understood that numerous other modifications and variations can be devised without departing from the scope of the invention.

What is claimed is:

1. A carbon nanotube forming apparatus for growing a carbon nanotube on a substrate, comprising:
a vacuum chamber for receiving a substrate therein;
an evacuation element for maintaining a predetermined degree of vacuum in said vacuum chamber;
a holding element for holding the substrate in said vacuum chamber; and
a radical beam irradiation element for generating a plasma from a source gas containing carbon to emit neutral radical species present in the plasma, thereby irradiating the substrate held by said holding element with the neutral radical species.

2. The carbon nanotube forming apparatus according to claim 1, wherein:
said radical beam irradiation element includes
a plasma generating chamber for introducing said source gas therein to generate the plasma, and
an aperture plate provided at a distal end of said plasma generating chamber and having an aperture formed therein; and
said radical beam irradiation element emits the neutral radical species through said aperture.

3. The carbon nanotube forming apparatus according to claim 1, further comprising
a radical shutter member for shutting off the radical species directed from said radical beam irradiation element toward the substrate.

4. The carbon nanotube forming apparatus according to claim 1, further comprising
a nanoparticle beam irradiation element for emitting nanoparticles containing at least one type of metal selected from the group consisting of cobalt, nickel and iron to irradiate the substrate held by said holding element with the nanoparticles.

5. The carbon nanotube forming apparatus according to claim 4, further comprising
a nanoparticle shutter member for shutting off the nanoparticles directed from said nanoparticle beam irradiation element toward the substrate.

6. The carbon nanotube forming apparatus according to claim 1, further comprising
an ion arrival inhibition element for inhibiting ionic species leaking from said radical beam irradiation element from arriving at the substrate held by said holding element.

7. The carbon nanotube forming apparatus according to claim 1, wherein
said holding element includes a heating element for heating the substrate held by said holding element to a predetermined temperature.

8. The carbon nanotube forming apparatus according to claim 1, further comprising:
a moving element for moving said holding element along a plane parallel to a main surface of the substrate held by said holding element; and
a rotating element for rotating said holding element about the central axis of the substrate held by said holding element.

9. The carbon nanotube forming apparatus according to claim 1, wherein
said radical beam irradiation element includes an ICP device for generating an inductively coupled plasma from the source gas.

10. The carbon nanotube forming apparatus according to claim 1, wherein
said radical beam irradiation element includes an ECR device for generating an electron cyclotron resonance plasma from the source gas.

11. A method of growing a carbon nanotube on a substrate received in a vacuum chamber to form the carbon nanotube, comprising the steps of:
a) maintaining a predetermined degree of vacuum in said vacuum chamber;
b) introducing a source gas containing carbon into a radical beam irradiation element to generate a plasma in said radical beam irradiation element; and
c) emitting neutral radical species present in the generated plasma from said radical beam irradiation element to irradiate a substrate held in said vacuum chamber with the neutral radical species.

12. The method according to claim 11, wherein
the neutral radical species are emitted from said radical beam irradiation element through an aperture formed in said radical beam irradiation element.

13. The method according to claim 11, further comprising the step of
d) irradiating the substrate held in said vacuum chamber with nanoparticles containing at least one type of metal selected from the group consisting of cobalt, nickel and iron, said step d) being performed prior to said step c).

14. The method according to claim 11, wherein
said step c) includes the step of heating the substrate to a predetermined temperature.
